(19) United States
(12) Patent Application Publication
(10) Pub. No.: US 2010/0308393 A1
(43) Pub. Date: Dec. 9, 2010

(54) SEMICONDUCTOR DEVICE AND METHOD OF MANUFACTURING THE SAME

(75) Inventors: Kazuhiro Matsuo, Yokkaichi (JP); Masayuki Tanaka, Yokohama (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/722,111

(22) Filed: Mar. 11, 2010

(30) Foreign Application Priority Data
Jun. 4, 2009 (JP) 2009-135015

(51) Int. Cl. H01L 29/788; H01L 21/336

(52) U.S. Cl. 257/316; 438/593; 438/258; 257/E21.68; 257/E21.422; 257/E29.3; 257/E27.103

(57) ABSTRACT

A semiconductor device including a semiconductor substrate having an active region isolated by an element isolation insulating film; a floating gate electrode film formed on a gate insulating film residing on the active region; an interelectrode insulating film formed above an upper surface of the element isolation insulating film and an upper surface and sidewalls of the floating gate electrode film, the interelectrode insulating film being configured by multiple film layers including a high dielectric film having a dielectric constant equal to or greater than a silicon nitride film; a control gate electrode film formed on the interelectrode insulating film; and a silicon oxide film formed between the upper surface of the floating gate electrode film and the interelectrode insulating film; wherein the high dielectric film of the interelectrode insulating film is placed in direct contact with the sidewalls of the floating gate electrode film.

### CROSS-REFERENCE TO RELATED APPLICATIONS

This application is based upon and claims the benefit of priority from the prior Japanese Patent Application No. 2009-135015, filed on, Jun. 4, 2009, the entire contents of which are incorporated herein by reference.

### FIELD

The present disclosure relates to a semiconductor device and a method of manufacturing such semiconductor device.

### BACKGROUND

A semiconductor device, typically a flash memory is provided with memory cells configured by memory cell transistors having an intergate insulating film provided between the floating gate electrode film and the control gate electrode film. The primary feature required in the above described intergate insulating film is preventing charge transfer. To elaborate, during writing, charge is prevented from leaking toward the control gate electrode, whereas during erasing, charge is prevented from being injected into the floating gate electrode from the control gate electrode. When the intergate insulating film lacks or is insufficient in such leak current property, the charge leak toward the control gate electrode during writing causes reduced write speed and saturation of write threshold, whereas during erasing, charge injection into the charge storing layer, that is, the floating gate electrode from the control gate electrode causes reduced erase speed and saturation of erase threshold. Such degradation in device properties calls for improvement in the insulation properties of the intergate insulating film.

One example of an intergate insulating film with improved insulation property is disclosed, for instance, in US published patent application US 2008/0277716. The publication discloses an intergate insulating film comprising a laminated structure of namely a silicon nitride film, a metal oxide film, more specifically, an aluminum oxide film and a silicon nitride film. The above described configuration has provided outstanding improvement in the insulation properties of the intergate insulating film.

However as the memory cell itself and the spacing between the neighboring memory cells become smaller with increasing density of memory cells, the percentage of floating gate electrodes having edges subject to concentrated electric field during write operation is increased to disadvantageously increase the high field leak, consequently preventing writing to the desired threshold. Thus, further improvement is required in the insulation property of the intergate insulating film.

### SUMMARY

According to an aspect of the invention, there is provided a semiconductor device including a semiconductor substrate having an active region isolated by an element isolation insulating film; a floating gate electrode film formed on a gate insulating film residing on the active region; an interelectrode insulating film formed above an upper surface of the element isolation insulating film and an upper surface and sidewalls of the floating gate electrode film, the interelectrode insulating film being configured by multiple film layers including a high dielectric film having a dielectric constant equal to or greater than a silicon nitride film; a control gate electrode film formed on the interelectrode insulating film; and a silicon oxide film formed between the upper surface of the floating gate electrode film and the interelectrode insulating film; wherein the high dielectric film of the interelectrode insulating film is placed in direct contact with the sidewalls of the floating gate electrode film.

According to an aspect of the invention, there is provided a method of manufacturing a semiconductor device including forming a gate insulating film on a semiconductor substrate; forming a floating gate electrode film on the gate insulating film; forming an element isolation trench into the semiconductor substrate, the gate insulating film and the floating gate electrode film; filling an element isolation insulating film in the element isolation trench such that an upper surface and upper sidewalls of the floating gate electrode film are exposed; forming an insulating film having a first thickness on the upper surface of the floating gate electrode film and a second thickness less than the first thickness on the upper sidewalls of the floating gate electrode film; removing the insulating film formed on the upper sidewalls of the floating gate electrode film by isotropic etching while leaving the insulating film on the upper surface of the floating gate electrode film; forming an interelectrode insulating film above the upper surface of the element isolation insulating film, and the upper surface and the upper sidewalls of the floating gate electrode film; and forming a control gate electrode film on the interelectrode insulating film.

### BRIEF DESCRIPTION OF THE DRAWINGS

FIG. 1 is a schematic plan view of a memory cell region according to one exemplary embodiment of the present invention;

FIG. 2A is a cross sectional view taken along line 2A-2A of FIG. 1;

FIG. 2B is an enlarged view of portion B of FIG. 2A;

FIG. 3 is a cross sectional view taken along line 3-3 of FIG. 1;

FIG. 4 is a cross sectional view indicating one phase of a manufacturing process;

FIG. 5 is a cross sectional view indicating another phase of the manufacturing process; and

FIG. 6 is a cross sectional view indicating yet another phase of the manufacturing process.

### DETAILED DESCRIPTION

One exemplary embodiment will be described with reference to the accompanying figures. Elements that are identical or substantially identical across the figures are identified with identical or similar reference symbols. It is to be further noted that the figures are schematic and do not reflect the actual measurement of the features such as the relation between thickness and planar dimensions and the ratio of thickness between each layer.

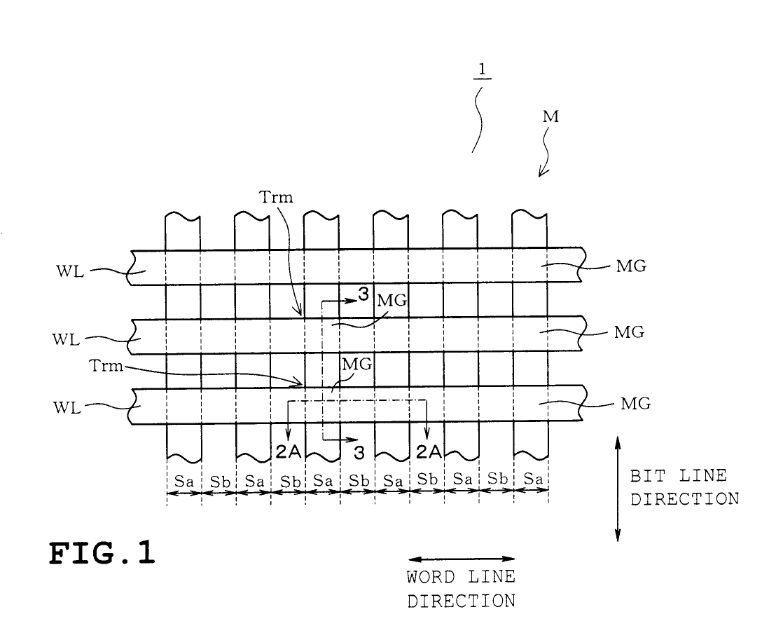

FIG. 1 is a plan view of a memory cell provided in a nonvolatile semiconductor storage device 1, hereinafter also simply referred to as a semiconductor device, according to the first exemplary embodiment. As shown in FIG. 1, memory cell region M includes multiplicity of memory cell transistors Trm in matrix alignment of the word line direction and bit line direction. Data stored in memory cell transistors Trm is read, written, and erased by a peripheral circuit not shown. One example of a nonvolatile semiconductor storage device employing the above described memory cell structure is a NAND flash memory provided with a unit of memory cells also referred to as cell unit structure that comprises a multiplicity of series connected memory cell transistors situated between a couple of select gate transistors.

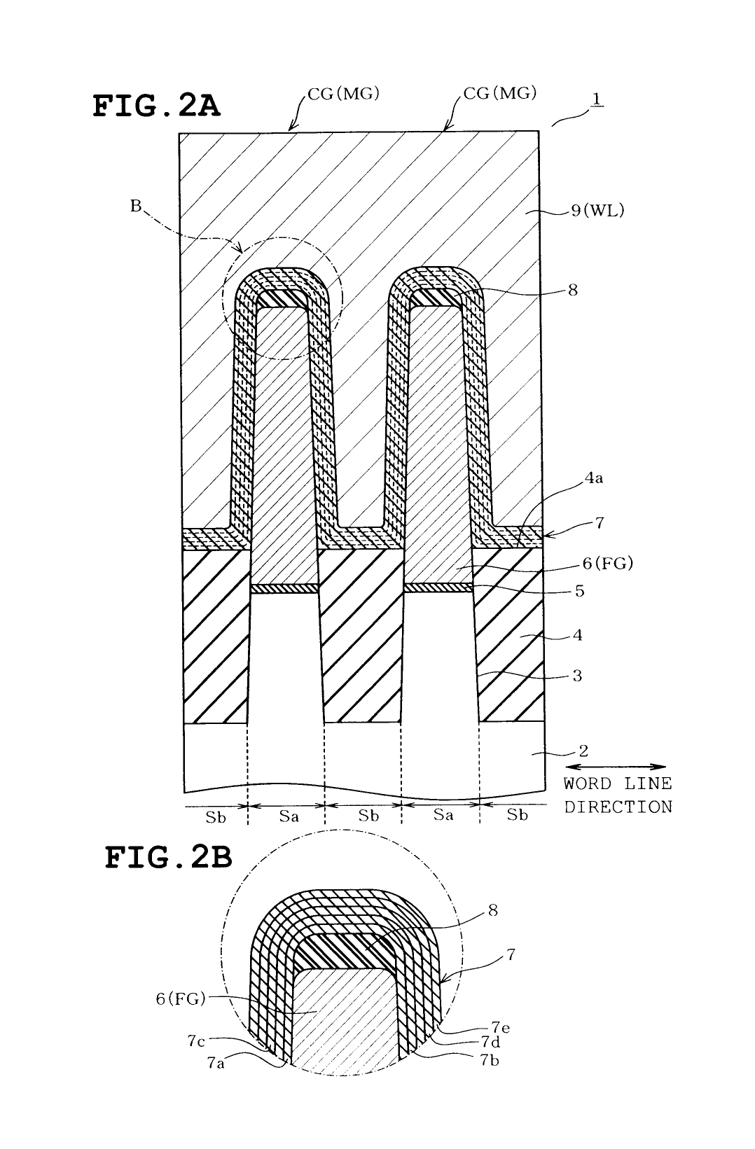

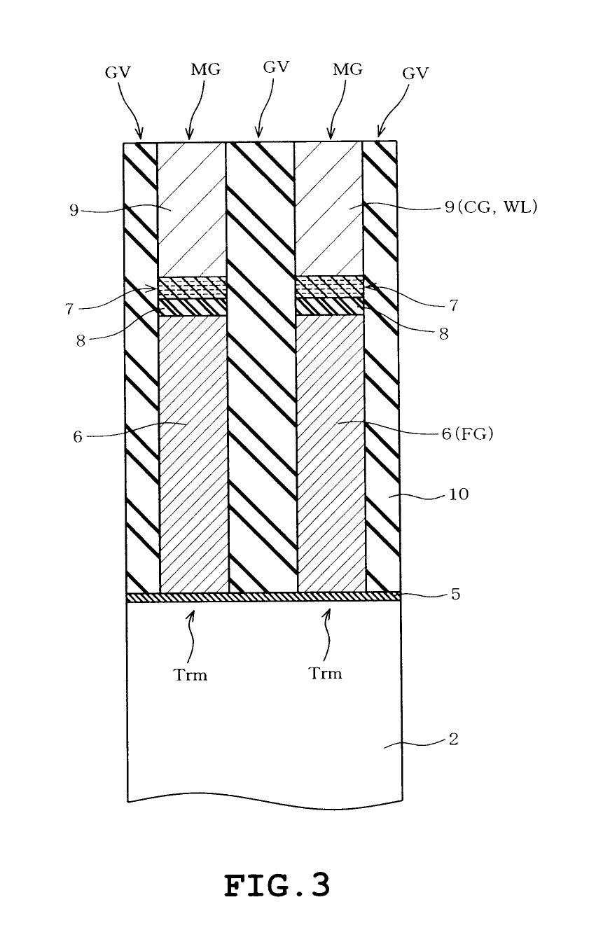

FIG. 2A is a cross sectional view taken along line 2A-2A of FIG. 1 or the word line direction or yet the channel width direction of each memory cell. FIG. 2B is an enlarged cross sectional view of portion B indicated in FIG. 2A. Further, FIG. 3 is a cross sectional view taken along line 3A-3A of FIG. 1 or the bit line direction or yet the channel length direction of each memory cell. As shown in FIG. 2A, on the surface layer of silicon substrate 2, or more generally, a semiconductor substrate, a plurality of element isolation trenches 3 are formed to isolate a plurality of active areas Sa along the word line direction of FIG. 2A.

Element isolation region Sb is formed by filling element isolation trench 3 with element isolation insulating film 4. Element isolation insulating film 4 comprises a lower portion filling the interior of element isolation trench 3 and an upper portion protruding upward from the surface of silicon substrate 2, or more specifically, from the surface of active area Sa of silicon substrate 2.

Active areas Sa in silicon substrate 2 that are delineated by element isolation regions Sb each have gate insulating film 5, in other words, tunnel insulating film formed on them. Gate insulating film 5 comprises, for instance, a silicon oxide film. On top of gate insulating film 5, floating gate electrode film FG is formed that serves as a charge storing layer. Floating gate electrode film FG comprises polycrystalline silicon layer 6 doped with impurities such as phosphorous to serve as a conductor layer or a semiconductor layer. Polycrystalline silicon layer 6 has a lower sidewall serving as an interface with the upper sidewall of element isolation insulating film 4 and an upper sidewall protruding higher upward from upper surface 4a of element isolation insulating film 4.

Above upper surface 4a of element isolation insulating film 4, the upper sidewalls of floating gate electrode film FG, and the upper surface of floating gate electrode film FG, interelectrode insulating film 7 is formed that is also known as an interpoly insulating film and an inter-conductor layer insulating film. Silicon oxide film 8 is formed between the upper surface of floating gate electrode film FG and interelectrode insulating film 7. As shown in FIG. 2B, interelectrode insulating film 7 comprises a first silicon nitride film 7a, a first silicon oxide film 7b, a second silicon nitride film 7c, a second silicon oxide film 7d, and a third silicon nitride film 7e laminated in listed sequence above upper surface 4a of element isolation insulating film 4, the upper sidewalls of floating gate electrode film FG, the sidewalls of silicon oxide film 8, and the upper surface of silicon oxide film 8.

On top of interelectrode insulating film 7, conductor layer 9 is formed along the word line direction. Conductor layer 9 serves as word line WL that establishes connection between control gate electrode film CG of each memory cell transistor Trm. Conductor layer 9 comprises, for instance, a polycrystalline silicon layer, and a silicide layer formed immediately on top of the polycrystalline silicon layer, which silicide layer is formed of a silicide of either of the metals selected from the group of tungsten, cobalt, and nickel. Thus, gate electrode MG of memory cell transistor Trm is configured by a so called stacked gate structure in which floating gate electrode film FG, interelectrode insulating film 7, and control gate electrode film CG are stacked over gate insulating film 5 in the listed sequence.

As shown in FIG. 3, gate electrodes MG of memory cell transistors Trm are aligned in the bit line direction and are electrically isolated from each other by isolation region GV. Within isolation region GV, interlayer insulating film 10 is formed for providing electric isolation. In the surface layer of silicon substrate 2 beside gate electrode MG of memory cell transistor MG, a diffusion layer not shown is formed that serves configured by gate insulating film 5, gate electrode MG, and source/drain regions.

Nonvolatile semiconductor storage device 1 allows erasing/writing of data to/from the memory cells by applying high electric field between word line WL and P well of silicon substrate 2 and applying the appropriate predetermined voltage on the relevant electrical components such as the source/drain region by the peripheral circuit not shown. To elaborate, when writing, the peripheral circuit applies high voltage on word line WL selected for writing as well as applying low voltage on P well etc., of silicon substrate 2. When erasing, on the other hand, the peripheral circuit applies low voltage on word line WL selected for erasing as well as applying high voltage on P well of silicon substrate 2.

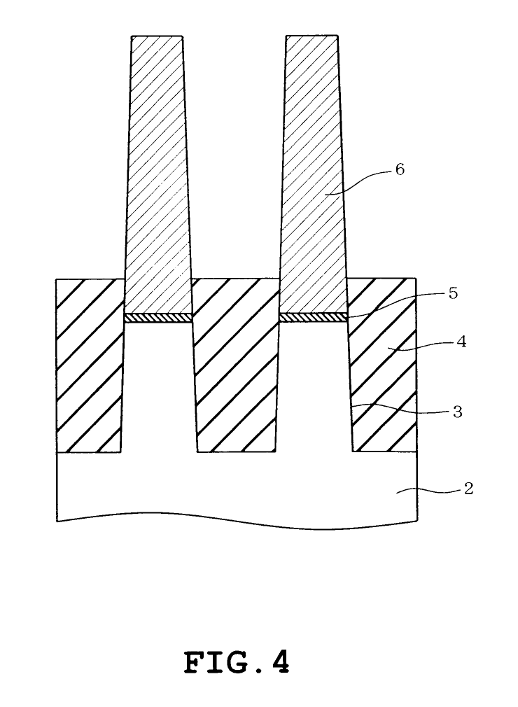

Next, a description will be given on a method of manufacturing the nonvolatile semiconductor storage device 1 described above with reference to FIGS. 4 to 6. As the first step of the manufacturing process, gate insulating film 5 serving as a tunnel insulating film is formed in the thickness of 6 nm, for instance, on silicon substrate 2 doped with impurities as shown in FIG. 4. Then on top of gate insulating film 5, polycrystalline silicon layer 6 serving as floating gate electrode film FG, in other words, charge storing layer is formed in the thickness of 100 nm, for instance, by CVD (Chemical Vapor Deposition).

Then, a silicon nitride film not shown serving as a mask is formed by CVD whereafter silicon oxide film not shown is further formed by CVD that also serves as a mask. Then, the silicon oxide film is coated with a photoresist not shown which is patterned by lithographic exposure.

Then, using the patterned photo resist as an anti-etching mask also referred to as a first resist mask, the silicon oxide film is etched by RIE (Reactive Ion Etching). After etching, the photoresist is removed and the silicon oxide film is used as mask for etching the silicon nitride film by RIE. Thereafter, polycrystalline silicon layer 6 serving as floating gate electrode film FG, gate insulating film 5, and silicon substrate 2 are etched to form element isolation trenches 3 that provide element isolation. To elaborate, the widths of both the element forming region and element isolation trench 3 are approximately 50 nm. Then, element isolation insulating film 4 made of silicon oxide film is formed above the silicon oxide film and into element isolation trenches 3 using polysilazane coating techniques to fill element isolation trenches 3.

Then, the silicon oxide film residing on the silicon nitride film is removed by CMP (Chemical Vapor Deposition) planarization using the silicon nitride film as a stopper to leave the silicon oxide film serving as element isolation insulating film 4 within element isolation trench 3. Then, silicon nitride film serving as a mask is etched away by chemical solution to expose the upper surface of polycrystalline silicon layer 6. Then, the upper portion of the silicon oxide film serving as element isolation insulating film 4 is etched away by dilute hydrofluoric acid to expose the upper sidewalls of polycrystalline silicon layer 6. The height of the exposed sidewalls is approximately 50 nm. The above described steps obtain the feature shown in FIG. 4 where element isolation insulating film 4 is filled in element isolation trench 3.

Next, as shown in FIG. 2A, silicon oxide film 8 is formed on the upper surface of floating gate electrode film FG whereafter interelectrode insulating film 7 is formed on the entire underlying surface, that is, upper surface 4a of element isolation insulating film 4, the upper sidewalls of floating gate electrode film FG, and the sidewalls and the upper surface of silicon oxide film 8. The details will be later described as to how silicon oxide film 8 and interelectrode insulating film 7 are formed.

Then, on top of interelectrode insulating film 7, conductor layer 9 serving as control gate electrode film CG is formed in the thickness of 100 nm, for instance. Conductor layer 9 is a laminated structure of tungsten silicide film formed over polycrystalline silicon film. Further, a silicon nitride film not shown is deposited by CVD to serve as a mask for subsequent RIE. Then, a second resist mask not shown, which is patterned to be oriented orthogonal to the first resist mask, is formed on the silicon nitride film. Then, using the second resist mask, the silicon nitride film serving as a mask, conductor layer 9, intergate insulating film 7, silicon oxide film 8, and polycrystalline silicon layer 6 are etched by RIE in listed sequence. Floating gate electrode film FG serving as a charge storing layer and control gate electrode film CG serving as the control electrode are formed by the above described steps. The width of each floating gate electrode film FG and the spacing between floating gate electrode films FG are both approximately 50 nm.

Next, gate sidewall film not shown is formed in the thickness of approximately 10 nm by thermal oxidation and CVD. Then, an impurity diffusion layer not shown constituting the source/drain region is formed by ion implantation and annealing. Further, interlayer insulating film 10 is formed using methods such as CVD. Thereafter, wiring and other features not shown are formed by known techniques.

Nonvolatile semiconductor storage device 1 comprising gate insulating film 5 formed on silicon substrate 2 serving as a semiconductor substrate, floating gate electrode film FG formed on gate insulating film 5, interelectrode insulating film formed on floating gate electrode film FG, control gate electrode film CG formed on interelectrode insulating film 7, and the impurity diffusion layer formed at both sides of the channel region under floating gate electrode film FG are formed by the above described steps.

In each memory cell of nonvolatile semiconductor storage device 1 obtained by the above described steps, high level voltage is applied between silicon substrate 2 and control gate electrode film CG. The application of high level voltage causes electric field corresponding to the coupling ratio to be applied to gate insulating film 5, which in turn flows tunnel current at gate insulating film 5. As a result, the amount of charge stored at floating gate electrode film FG is altered to cause a change in the threshold of the memory cell and consequently write or erase data to and from the memory cell. In the actual nonvolatile semiconductor storage device 1, multiple memory cells are aligned in the word line direction and the bit line direction.

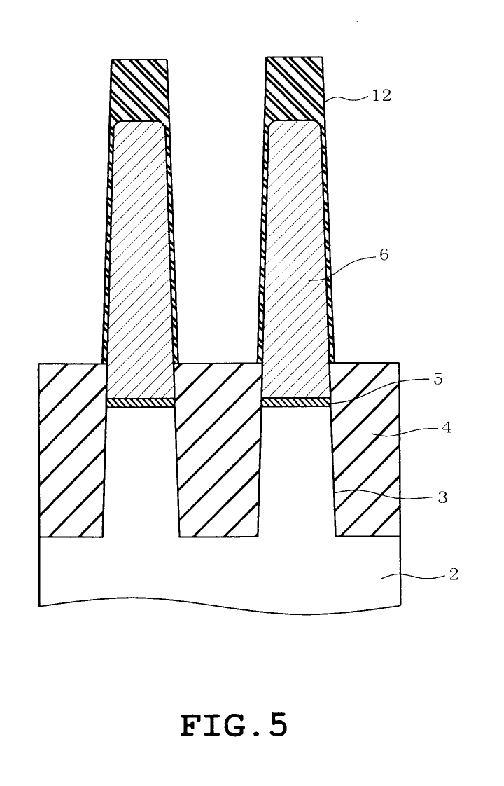

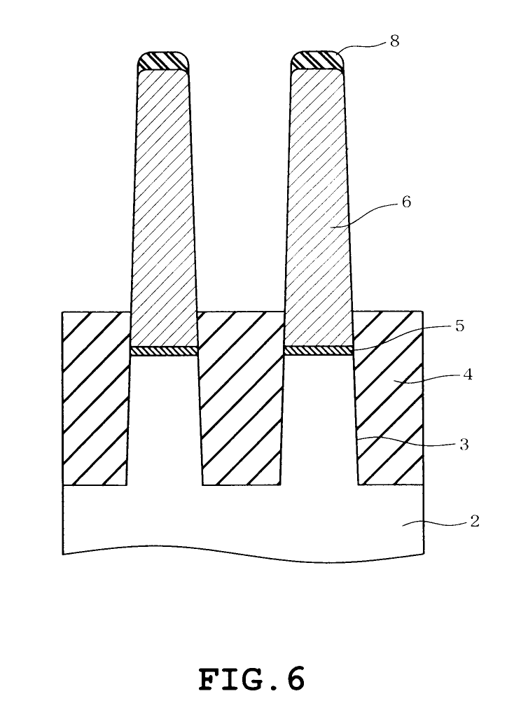

The formation of silicon oxide film 8 and interelectrode insulating film 7 will be described in more detail hereinafter. Referring to FIG. 4, after exposing the upper surface and the sidewalls of polycrystalline silicon layer 6 serving as floating gate electrode film FG, relatively thick silicon oxide film 12 is formed on the upper surface of polycrystalline silicon layer 6 and relatively thin silicon oxide film 12 is formed on the sidewalls of polycrystalline silicon layer 6 by anisotropic oxidation as shown in FIG. 5. Then, as shown in FIG. 6, silicon oxide film 12 residing on the sidewalls of polycrystalline silicon layer 6 is removed by isotropic wet etching using chemical solution etc., so that silicon oxide film 12 remains on the upper surface of polycrystalline silicon layer 6. This results in the formation of silicon oxide film 8 on the upper surface of polycrystalline silicon layer 6. When forming silicon oxide film 12 on the upper surface of polycrystalline silicon layer 6 by anisotropic oxidation, the edges of floating gate electrode film FG being subjected to relatively greater exposure to oxidative agent are rounded by the increased oxidation. When the edges of floating gate electrode film FG are rounded, charge leak due to concentrated electric field at the edges of floating gate electrode film FG can be reduced to improve the write speed and saturation of write threshold.

The anisotropic oxidation for forming silicon oxide film 12 will be described in detail hereinafter. In the present exemplary embodiment, microwaves were generated in an oxygen gas containing atmosphere to generate oxygen radical and oxygen ion which anisotropically oxidizes the surface of polycrystalline silicon layer 6 to form silicon oxide film 12. The parameters were set as follows: microwave output at 500 to 5000 W, bias for drawing the ions toward silicon substrate at 0.1 to 300 mW/cm, process pressure at 20 to 800 Pa, and substrate temperature at room temperature to 800 degrees Celsius.

Alternative approach to the above described anisotropic oxidation of polycrystalline silicon layer 6 surface employs oxidation agent, generated by reaction between hydrogen gas and oxygen gas. This approach yields greater efficiency or formation rate in forming silicon oxide film 12. Under this approach, the preferable ratio of hydrogen gas in the mixture gas of oxygen and hydrogen is 0.01 to 30%.

By isotropic wet etching silicon oxide film 12 formed by the above described steps, the features shown in FIG. 6 can be obtained in which silicon oxide film 12 on the sidewalls of polycrystalline silicon layer 6 is removed to leave silicon oxide film 8 on the upper surface of polycrystalline silicon layer 6. As can be seen in FIG. 6, silicon oxide film 12 residing on the upper surface of polycrystalline silicon layer 6 is thinned by the isotropic etching. The isotropic etching for removing silicon oxide film 12 residing on the sidewalls of polycrystalline silicon layer 6 is not limited to the above described wet etching with chemical solution but may take any other approaches such as chemical dry etching. By employing isotropic etching such as those described above, silicon oxide film 12 residing on the sidewalls of polycrystalline silicon layer 6 can be removed while maintaining silicon oxide film 12 on the upper surface of polycrystalline silicon layer 6, in other words, at the top of floating gate electrode film FG. By removing silicon oxide film 12 on the sidewalls of polycrystalline silicon layer 6, the width of the gaps between the neighboring polycrystalline silicon layers 6 can be widened to reduce the aspect ratio. Further, because the etching progresses in the vertical and horizontal directions, the upper edge of the remainder silicon oxide film 8 can be rounded. Thus, the gap fill capability can be improved in filling the gaps between the neighboring polycrystalline silicon layers 6 with control gate electrode film CG via interelectrode insulating film 7. The amount of anistropic oxidation and isotropic wet etching may be adjusted to any given amounts as long as the adjusted amount allow the removal of silicon oxide film 12 from the sidewalls of polycrystalline silicon layer 6 while maintaining silicon oxide film 12 on the upper surface of polycrystalline silicon layer 6.

In chemical dry etching, silicon oxide film 12 is removed by reaction gas and sublimation and thus, the thickness or the amount of silicon oxide film 12 that can be etched away in a single execution of chemical dry etching is determined by the process being employed. Hence, when removing silicon oxide 12 film on the sidewalls of polycrystalline silicon layer 6 by chemical dry etching, anisotropic oxidation shall be executed based upon the amount/thickness of silicon oxide film 12 that can be removed by the chemical dry etching. To elaborate, if 5 nm of silicon oxide film 12 can be removed in a single execution of chemical dry etching, silicon oxide film 12 which is more than 5 nm thick shall be formed on the upper surface of polycrystalline silicon layer 6 and silicon oxide film 12 equal to or less than 5 nm thick shall be formed on the sidewalls of polycrystalline silicon layer 6 by anisotropic oxidation. By executing the isotropic etching after the above described anisotropic oxidation, silicon oxide film 12 on the sidewalls of polycrystalline silicon layer 6 can be removed while maintaining silicon oxide film 12 on the upper surface of polycrystalline silicon layer 6.

If the upper surface of polycrystalline silicon layer 6 serving as floating gate electrode film FG occupies relatively greater area of interelectrode insulating film 7, it is desirable to, for instance, increase the thickness of silicon oxide film 8 remaining on the upper surface of polycrystalline silicon layer 6. However, increase in the thickness of silicon oxide film 8 on the upper surface of floating gate electrode film FG reduces the capacitance of interelectrode insulating film 7, thereby reducing the voltage applied on tunnel insulating film 5 or the coupling ratio during the write operation. This in turn reduces the write threshold and may provide negative impact on device operation. In order to obtain the desired coupling ratio, the area of contact between sidewalls of polycrystalline silicon layer 6 and interelectrode insulating film 7 may be increased or the thickness of interelectrode insulating film 7 may be reduced to achieve an increase in capacitance. Further, it is known that the level of electric field applied on interelectrode insulating film 7 is inversely proportionate to the electric film thickness of interelectrode insulating film 7. Electric film thickness, in this case, indicates the equivalent oxide thickness known as EOT. Thus, in order to reduce the intensity of the electric field at the edges of the floating gate electrode FG, the percentage of increase in the electric film thickness of interelectrode insulating film 7 by silicon oxide film 8 shall be controlled so that it does not exceed the percentage of increase in the intensity of electric field at the edges of floating gate electrode film FG. In view of forming an insulating film being sufficiently thick in electric film thickness on the upper surface of floating gate electrode film FG for achieving the reduction in the intensity of electric field at the edges of the floating gate electrode FG, the choice of silicon oxide film 8 to serve as the insulating film yields the same level of reduction in high electric field leak as compared to employing high dielectric films such as a silicon nitride film in a much smaller physical film thickness. As a result, increase in the aspect ratio of the gaps between the neighboring polycrystalline silicon layers 6 caused by formation of an additional insulating film below interelectrode insulating film 7 can be prevented. This minimizes the negative impact on the gap fill capability in filling the gaps between the polycrystalline silicon layers 6 with control gate electrode film CG.

Further, because coating type insulating film is employed as element isolation insulating film 4 for filling the element isolation trench 3 in the present exemplary embodiment with the utmost priority placed on providing favorable gap fill capability, element isolation insulating film 4 thus, may contain multiple instances of impurities such as carbon, nitride, and chloride or defects such as a dangling bond in which bond is not established between silicon contained in the insulating film and oxygen. Excess of such impurities and defects may cause leaks of electrons written in the floating gate electrode film FG through the trap originating from the above described impurities and defects in the element isolation insulating film 4 situated between the floating gate electrode films FG or the memory cells. Such electron leak is likely to degrade the charge storing properties of the device. To address such concerns, the present exemplary embodiment diffuses the impurities contained in element isolation insulating film 4 outward or inward when anisotropically oxidating the surface of floating gate electrode FG serving as polycrystalline silicon layer 6. Thus, amount of impurities residing at the proximity of the sidewalls of floating gate electrode film FG can be reduced. The defects in element isolation insulating film 4 can be alleviated by active oxygen supplied to it to compensate for the lack of oxygen. By alleviating the defects of element isolation insulating film 4, improvement of charge storing properties and thickening of silicon oxide film 8 formed on the upper surface of floating gate electrode film FG can be achieved at the same time.

After forming silicon oxide film 8 on the upper surface of polycrystalline silicon layer 6 serving as floating gate electrode film FG, the first silicon nitride film 7a is formed on upper surface 4a of element isolation insulating film 4, the upper sidewall of polycrystalline silicon layer 6 and the sidewalls and the upper surface of silicon oxide film 8 as shown in FIG. 2A. To elaborate, the first silicon nitride film 7a is formed by reaction of zichlorosilane and ammonia in the temperature of approximately 800 degrees Celsius. Then, silicon oxide film 7b is formed on the upper surface of silicon nitride film 7a by CVD. To elaborate, the first silicon oxide film 7b is formed by reaction of zichlorosilane with nitrogen monoxide (N₂O) in the temperature of approximately 800 degrees Celsius.

Then, the second silicon nitride film 7c is formed on the upper surface of the first silicon oxide film 7b by CVD. The second silicon nitride film 7c is obtained by reaction of zichlorosilane and ammonia in the temperature of approximately 800 degrees Celsius. Then, the second silicon oxide film 7d is formed on the upper surface of the second silicon nitride film 7c by CVD. The second silicon oxide film 7b is obtained by reaction of zichlorosilane with nitrogen monoxide (N₂O) in the temperature of approximately 800 degrees Celsius. Then, the third silicon nitride film 7e is formed on the upper surface of the second silicon oxide film 7d. The third silicon nitride film 7e is obtained by reaction of zichlorosilane and ammonia in the temperature of approximately 800 degrees Celsius by CVD. Thus, interelectrode insulating film 7, in other words, a NONON film is formed that comprises the first silicon nitride film 7a, the first silicon oxide film 7b, the second silicon nitride film 7c, the second silicon oxide film 7d, and the third silicon nitride film 7e.

According to the above described exemplary embodiment, silicon oxide film 8 is formed, as an additional insulating film, between the upper surface of floating gate electrode film FG and the interelectrode insulating film 7. Thus, leak of high electric field can be reduced by reducing the concentration of electric field at interelectrode film 7 during the write operation even under shrunk memory cell dimension and reduced gaps between the neighboring memory cells imposed by increasing densification of memory cells, which further improves the insulation property of interelectrode insulating film 7. Especially because the present exemplary embodiment employs silicon oxide film 8 as the insulating film formed on floating gate electrode film FG, the insulating property can be improved in small physical thickness to thereby prevent degradation in the gap fill capability of control gate electrode film CG. Further, the present exemplary embodiment places interelectrode insulating film 7, more specifically, the first silicon nitride film 7a having relatively high dielectric constant in direct contact with the sidewalls of floating gate electrode film FG. Thus, electrons are forced to travel relatively greater distance in tunneling from the sidewalls of floating gate electrode FG in response to the application of high electric field, which reduces the occurrence of leak from the sidewalls of floating gate electrode FG.

Further, when forming silicon oxide film 8, the former silicon oxide film 12, on the upper surface of polycrystalline silicon layer 6 by anisotropic oxidation, the edges of floating gate electrode film FG being subjected to relatively greater exposure to oxidative agent are rounded by the increased oxidation. When the edges of floating gate electrode film FG are rounded, charge leak due to concentrated electric field at the edges of floating gate electrode film FG can be reduced all the more to improve the write speed and saturation of write threshold.

Further, the spacing between the floating gate electrode films FG can be increased and the edges of the obtained silicon oxide film 8 itself can be rounded when isotropically etching silicon oxide film 12. Thus, control gate electrode film CG can be filled in the gaps between floating gate electrode films FG in sufficient amounts while increasing the coupling ratio.

Yet, further, because coating type insulating film is employed as element isolation insulating film for filling the element isolation trench 3 in the present exemplary embodiment to prioritize favorable gap fill capability, the impurities contained in element isolation insulating film 4 are diffused outward or inward when anisotropically oxidating the surface of floating gate electrode FG serving as polycrystalline silicon layer 6. Thus, amount of impurities residing at the proximity of the sidewalls of floating gate electrode film FG can be reduced. Further, defects in element isolation insulating film 4 can be alleviated by active oxygen supplied to it to compensate for the lack oxygen. By alleviating the defects of element isolation insulating film 4, improvement of charge storing properties and thickening of silicon oxide film 8 formed on the upper surface of floating gate electrode film FG can be achieved at the same time.

The present exemplary embodiments but may be modified or expanded as follows.

In the above described exemplary embodiment, silicon oxide film 12 is formed by anisotropic oxidation to be relatively thicker on the upper surface of polycrystalline silicon layer 6 and relatively thinner on the sidewalls of polycrystalline silicon layer 6. However, silicon oxide film 12 may be formed by sputtering, for instance, so as to be relatively thicker on the upper surface of polycrystalline silicon layer 6 and thinner on the sidewalls of polycrystalline silicon layer 6. Further, if electric film thickness that allows reduction in electron leak can be obtained without having to substantially increasing the physical thickness of the insulating film, insulating films other than silicon oxide film may be formed so as to be relatively thicker on the upper surface of polycrystalline silicon layer 6 and thinner on the sidewalls of polycrystalline silicon layer 6.

Still further, the above described exemplary embodiment employs intereletrode insulating film 7 that employs five layers of insulating films namely, the first silicon nitride film 7a, the first silicon oxide film 7b, the second silicon nitride film 7c, the second silicon oxide film 7d, and the third silicon nitride film 7e. However, the number of layers is not limited to five and the laminated layers may comprise high dielectric film/silicon oxide film/silicon nitride film structure in which the lowermost layer employs high dielectric film other than silicon nitride film. High dielectric film, in this case, indicates insulating films having equal or greater dielectric constant than silicon nitride film. Examples of replacement single layer high dielectric films are either of: silicon nitride film (Si₃N₄) having relative dielectric constant of 7 times of greater, aluminum oxide film (Al₂O₃) having relative dielectric constant of 8 times or greater, magnesium oxide film (MGO) having relative dielectric constant of 10 times or greater, yttrium oxide film (Y₂O₃) having relative dielectric constant of 16 times or greater, and hafnium oxide film (HfO₂), zirconium oxide (ZrO₂)ᵣ and lanthanum oxide (La₂O₃) having relative dielectric constant of 22 times or greater. Insulating films comprising tri-element compound such as hafnium silicate film (HfSiO) and hafnium aluminate (HfAlO) may also be employed. Stated differently, an oxide film or nitride film containing at least one element from aluminum (Al), magnesium (Mg), yttrium (Y), hafnium (Hf), zirconium (Zr), and lanthanum (La) may be employed.

Still further, silicon nitride films 7a, 7c, and 7e of interelectrode insulating film 7 have been formed by CVD, however, they may be formed by ALD (Atomic Layer Deposition), thermal nitridation, radical nitridation or sputtering.

Still further, the above described exemplary embodiment has been described through an example of NAND flash memory, however, an alternative exemplary embodiment may employ other types of nonvolatile semiconductor storage device such as a NOR flash memory.

The foregoing description and drawings are merely illustrative of the principles of the present invention and are not to be construed in a limited sense. Various changes and modifications will become apparent to those of ordinary skill in the art. All such changes and modifications are seen to fall within the scope of the disclosure as defined by the appended claims.

What is claimed is:

1. A semiconductor device, comprising:
a semiconductor substrate having an active region isolated by an element isolation insulating film;
a floating gate electrode film formed on a gate insulating film residing on the active region;
an interelectrode insulating film formed above an upper surface of the element isolation insulating film and an upper surface and sidewalls of the floating gate electrode film, the interelectrode insulating film being configured by multiple film layers including a high dielectric film having a dielectric constant equal to or greater than a silicon nitride film;
a control gate electrode film formed on the interelectrode insulating film; and
a silicon oxide film formed between the upper surface of the floating gate electrode film and the interelectrode insulating film;
wherein the high dielectric film of the interelectrode insulating film is placed in direct contact with the sidewalls of the floating gate electrode film.

2. The semiconductor device according to claim 1, wherein the multiple film layers of the interelectrode insulating film includes a lowermost first silicon nitride film, a first silicon oxide film, a second silicon nitride film, a second silicon oxide film, and an upper most third silicon nitride film laminated in listed sequence.

3. The semiconductor device according to claim 1, the silicon oxide film formed between the upper surface of the floating gate electrode film and the interelectrode insulating film is formed by anisotropically oxidating a surface of the floating gate electrode film including edges thereof and thereafter removing the silicon oxide film on the sidewalls of the floating gate electrode film by isotropic etching.

4. The semiconductor device according to claim 3, wherein the element isolation insulating film comprises a coating type insulating film.

5. The semiconductor device according to claim 3, wherein the silicon oxide film formed between the upper surface of the floating gate electrode film and the interelectrode insulating film has rounded edges.

6. The semiconductor device according to claim 3, wherein the edges of the floating gate electrode film are rounded.

7. The semiconductor device according to claim 1, wherein the high dielectric film comprises a silicon nitride film or an oxide or a nitride film including at least one element selected from the group of aluminum, magnesium, yttrium, hafnium, zirconium, and lanthanum.

8. A method of manufacturing a semiconductor device comprising:
forming a gate insulating film on a semiconductor substrate;
forming a floating gate electrode film on the gate insulating film;
forming an element isolation trench into the semiconductor substrate, the gate insulating film and the floating gate electrode film;
filling an element isolation insulating film in the element isolation trench such that an upper surface and upper sidewalls of the floating gate electrode film are exposed;
forming an insulating film having a first thickness on the upper surface of the floating gate electrode film and a second thickness less than the first thickness on the upper sidewalls of the floating gate electrode film;
removing the insulating film formed on the upper sidewalls of the floating gate electrode film by isotropic etching while leaving the insulating film on the upper surface of the floating gate electrode film;
forming an interelectrode insulating film above the upper surface of the element isolation insulating film, and the upper surface and the upper sidewalls of the floating gate electrode film; and
forming a control gate electrode film on the interelectrode insulating film.

9. The method according to claim 8, wherein the insulating film having the first thickness on the upper surface of the floating gate electrode film and the second thickness less than the first thickness on the upper sidewalls of the floating gate electrode film comprises a silicon oxide film formed by anisotropically oxidating the upper surface and the upper sidewalls of the floating gate electrode film.

10. The method according to claim 9, wherein the anisotropic oxidation is executed by oxygen radicals and oxygen ions produced by microwaves generated in oxygen gas containing atmosphere.

11. The method according to claim 9, wherein the anisotropic oxidation is executed by an oxidating agent generated by a reaction of a hydrogen gas and an oxygen gas.

12. The method according to claim 8, wherein the isotropic etching is a wet etching using a chemical liquid.

13. The method according to claim 8, wherein the isotropic etching is a chemical dry etching.

14. The method according to claim 9, wherein the anisotropic oxidation rounds edges of the floating gate electrode film.

15. The method according to claim 9, wherein the isotropic etching rounds edges of the silicon oxide film left on the upper surface of the floating gate electrode film.

16. The method according to claim 9, wherein the element isolation insulating film comprises a coating type silicon oxide film.

17. The method according to claim 16, wherein the element isolation insulating film is enhanced by supplying an active oxygen when anisotropically oxidating the upper surface and the upper sidewalls of the floating gate electrode film.

18. The method according to claim 8, wherein the insulating film having the first thickness on the upper surface of the floating gate electrode film and the second thickness less than the first thickness on the upper sidewalls of the floating gate electrode film comprises a sputtered silicon oxide film.

19. The method according to claim 8, wherein forming the interelectrode insulating film includes placing a high dielectric film in direct contact with the upper sidewalls of the floating gate electrode film, the high dielectric film having a dielectric constant equal to or greater than a silicon nitride film.

20. The method according to claim 19, wherein forming the interelectrode insulating film includes laminating a lowermost first silicon nitride film, a first silicon oxide film, a second silicon nitride film, a second silicon oxide film, and an uppermost third silicon nitride film in listed sequence.
